(19) United States
(12) Patent Application Publication
(10) Pub. No.: US 2007/0093058 A1
(43) Pub. Date: Apr. 26, 2007

(54) METHOD FOR PRODUCING ELECTRIC CONTACT AND ELECTRICAL CONNECTOR

(76) Inventors: Tomonari Ohtsuki, Koto-ku (JP); Yasue Yamazaki, Koto-ku (JP)

Correspondence Address: BAKER & BOTTS L.L.P., 30 ROCKEFELLER PLAZA, 44TH FLOOR, NEW YORK, NY, 10112-4498, US

(21) Appl. No.: 11/551,444

(22) Filed: Oct. 20, 2006

(30) Foreign Application Priority Data
Oct. 24, 2005 (JP) 2005-309,085

(51) Int. Cl. H01L 21/44

(52) U.S. Cl. 438/687

(57) ABSTRACT

A method for producing an electric contact extending from a copper foil, comprises steps of fixing a cover lay having a hole of a diameter smaller than that of the copper foil of a predetermined size to the copper foil, and plating the hole of the cover lay so as to reach the upper surface of the cover lay as a first step; installing a dry film having a hole of a diameter smaller than that of the hole of the cover lay onto the cover lay, and plating the hole of the dry film so as to reach the upper surface of the dry film as a second step; and after removal of the dry film, as a third step further plating the plate layers obtained in the first and second steps. The electric contacts produced by the method have a predetermined height which is as high as possible and uniform without causing any defective connection between them. In a method for producing an electrical connector, diameters of the holes of the dry film in plating are changed depending upon positions of the electric contacts.

### BACKGROUND OF THE INVENTION

This invention relates to a method for producing electric contacts extending from respective copper foils, whose heights are uniform and as high as possible without increasing their diameters, and more particularly to a method for producing an electrical connector.

In bringing electronic components into contact with a circuit board, there have in the past been various cases that one is flat and the other is extended (for example, substantially in the form of a hemisphere), and one is extended and the other is flat as the case may be.

Patent Literature 1

According to the abstract of the Japanese Patent Application No. 2004-335,666, following a step of filling a blind hole with a metal in a manner that the conductor itself in the blind hole becomes a contact of a connector, with a view to separating out the metal so as to increase the volume of the conductor in the blind hole to form a hemispherical shape of the conductor on the outside of the blind hole, the inside of the blind hole is plated at first at a low current density, for example, of 0.5 to 10 A/dm², and after the plate layer has arrived at the upper surface of the blind hole, the current density is adjusted to be increased and while keeping a current density of five to ten times the initial current density value, the metal is separated out so that the conductor on the outside of the blind hole becomes hemispherical whose dimensional ratio of radius to height approximates to substantially 1:1.

Recently, on proceeding of miniaturization of electric and electronic appliances, electrical connectors have been miniaturized and their conductors have been arranged with narrower pitches. In producing electric contacts on copper foils, on the other hand, the ratio of radius to height of hemispherical electric contacts is usually approximately 1:1 as disclosed in the Patent Literature 1.

On proceeding of narrower pitches of electric contacts in recent years, however, when contacts of a certain height are formed, the diameter of the electric contacts becomes larger in comparison with distances between the contacts arranged with the narrower pitches so that the electric contacts are in close proximity to one another, thereby causing defective or failed electrical connection and short circuit. Even if the contacts are spaced apart from one another as much as possible to avoid such problems, the height of the contacts must necessarily be lowered so that even required predetermined height cannot be obtained.

With an electrical connector having electric contacts arranged and equally spaced from one another, moreover, if the electric contacts are formed by plating, irregularities in diameter and height of the electric contacts will occur during plating depending upon positions in which they are arranged. Such problems remain to be solved.

### SUMMARY OF THE INVENTION

In view of the problems of the prior art described above, the invention has an object to provide a method for producing electric contacts having a predetermined height (which is as high as possible and uniform) without causing any defective connection between them and has another object to provide a method for producing an electrical connector.

The above object can be achieved by the method for producing an electric contact 20 extending from a copper foil 40 according to the invention, comprising steps of fixing a cover lay 46 having a hole 42 of a diameter smaller than that of said copper foil 40 of a predetermined size to said copper foil, and plating said hole 42 of the cover lay 46 so as to reach the upper surface of the cover lay 46 as a first step; installing a dry film 50 having a hole 48 of a diameter smaller than that of said hole 42 of the cover lay 46 onto said cover lay 46, and plating said hole 48 of the dry film 50 so as to reach the upper surface of the dry film 50 as a second step; and after removal of said dry film 50, as a third step further plating the plate layers 44 obtained in the first and second steps.

According to the invention, the height of the produced electric contact 20 is greater than the radius (one half of diameter) of the electric contact 20.

The further object can be accomplished by the method for producing an electrical connector 10 including a plurality of said electric contacts 20 arranged with predetermined pitches according to the invention, in which diameters of the holes of the dry film 50 used in plating are changed depending upon positions of the electric contacts 20.

In the electrical connector wherein a plurality of said electric contacts 20 are arranged with predetermined pitches in a substantially square area, according to the invention diameters of said holes of the dry film 50 in the proximity of four corners of the square area are smaller than diameters of those in the proximity of four sides of the square area, and diameters of those in the inner side of the area other than those in the proximities of the four corners and the four sides are larger than the diameters of those in the proximity of the four sides of the square area.

As can be seen from the above description, the invention can bring about the following significant effects.

(1) The method for producing an electric contact 20 extending from a copper foil 40 according to the invention, comprises steps of fixing a cover lay 46 having a hole 42 of a diameter smaller than that of said copper foil 40 of a predetermined size to said copper foil, and plating said hole 42 of the cover lay 46 so as to reach the upper surface of the cover lay 46 as a first step; installing a dry film 50 having a hole 48 of a diameter smaller than that of said hole 42 of the cover lay 46 onto said cover lay 46, and plating said hole 48 of the dry film 50 so as to reach the upper surface of the dry film 50 as a second step; and after removal of said dry film 50, as a third step further plating the plate layers 44 obtained in the first and second steps. Consequently, by varying the thickness of the dry film 50, it becomes possible to make higher the electric contacts 20 and irregularities in heights of a plurality of electric contacts 20 can be avoided or electric contacts 20 of uniform heights can be obtained, thereby enabling any defective or failed connection to be prevented.

(2) According to invention, the height of the produced electric contact 20 is greater than the radius (one half of diameter) of the electric contact 20. Accordingly, irregularities in heights of a plurality of electric contacts 20 can be avoided, that is, electric contacts 20 are uniform in height so that accurate height of electric contacts 20 can be obtained to fully comply with customer's requirements even with narrower pitches, thereby enabling any defective or failed connection to be prevented.

(3) In the method for producing an electrical connector 10 including a plurality of said electric contacts 20 arranged with predetermined pitches, according to the invention diameters of the holes of the dry film 50 used in plating are changed depending upon positions of the electric contacts 20. Consequently, irregularities in heights of a plurality of electric contacts 20 can be avoided, that is, electric contacts 20 are uniform in height so that accurate height of electric contacts 20 can be obtained to fully comply with customer's requirements, thereby enabling any defective or failed connection to be prevented.

(4) In a method for producing an electrical connector 10 having a plurality of said electric contacts 20 arranged with predetermined pitches in a substantially square area, according to the invention diameters of said holes of the dry film 50 in the proximity of four corners of the square area are smaller than diameters of those in the proximity of four sides of the square area, and diameters of those in the inner side of the area other than those in the proximities of the four corners and the four sides are larger than the diameters of those in the proximity of the four sides of the square area. Therefore, irregularities in heights of a plurality of electric contacts 20 can be avoided, that is, electric contacts 20 are uniform in height so that accurate height of electric contacts 20 can be obtained to fully comply with customer's requirements, thereby enabling any defective or failed connection to be prevented.

The invention will be more fully understood by referring to the following detailed specification and claims taken in connection with the appended drawings.

### BRIEF DESCRIPTION OF THE DRAWINGS

FIG. 1 is a view illustrating the configuration of the electric contact according to the invention;

FIG. 2 is a view including a plan and a longitudinal-sectional view of the electrical connector according to the invention;

FIG. 3 is a view including a partly enlarged plan view and a partly enlarged longitudinal-sectional view of the electrical connector shown in FIG. 2;

FIGS. 4A to 4F are views for explaining the method for producing an electric contact according to the invention; and

FIG. 5 is a view for explaining the method for producing an electrical connector according to the invention.

### DESCRIPTION OF THE PREFERRED EMBODIMENTS

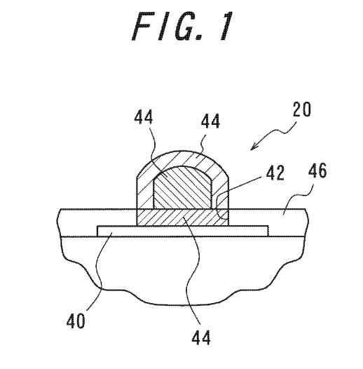

A method for producing an electric contact 20 and a method for producing an electrical connector 10 according to the invention will be explained with reference to FIGS. 1 to 5. In the present embodiment, the electrical connector 10 using the electric contacts 20 will be explained.

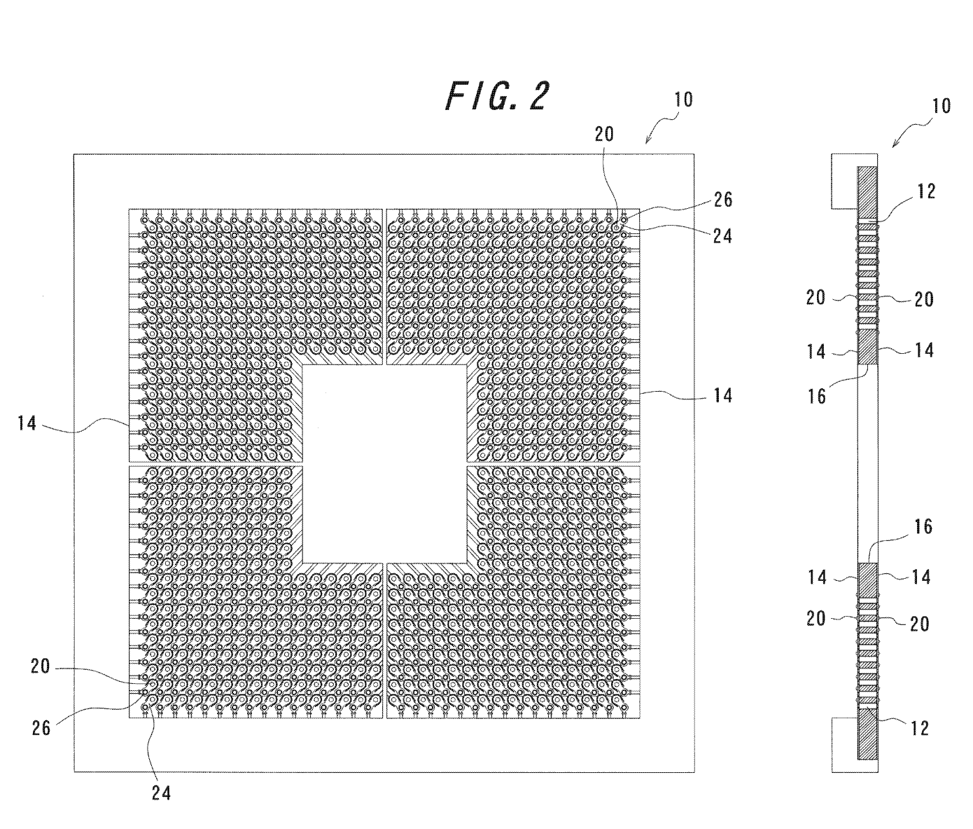

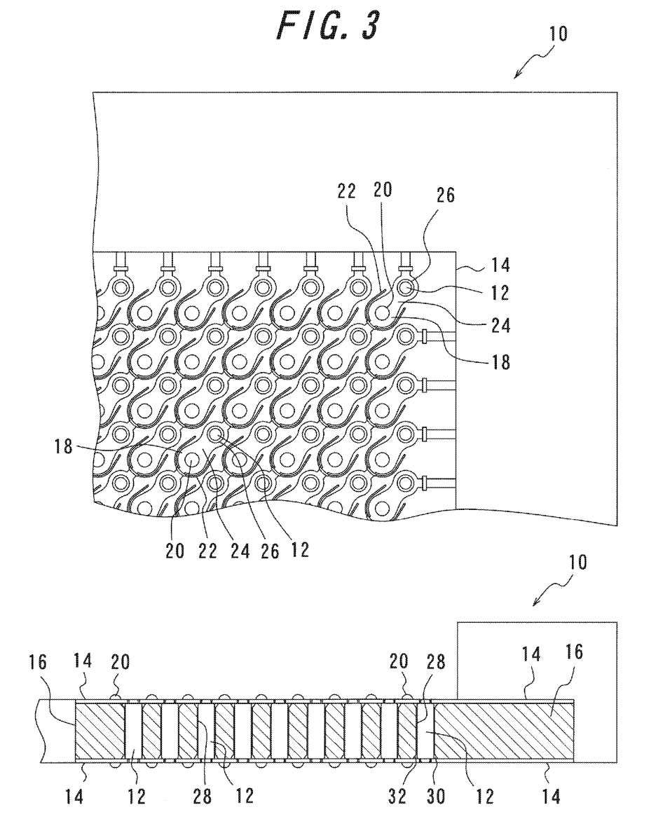

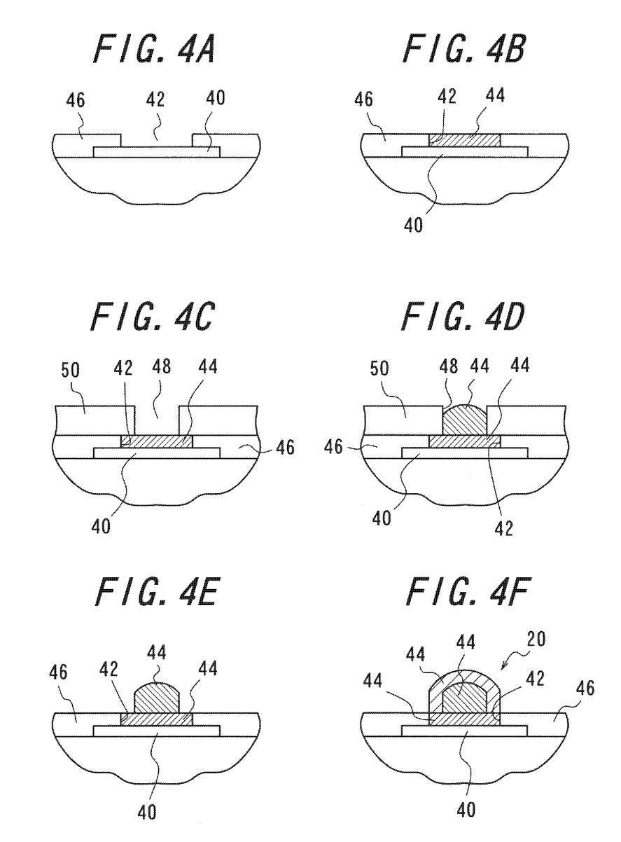

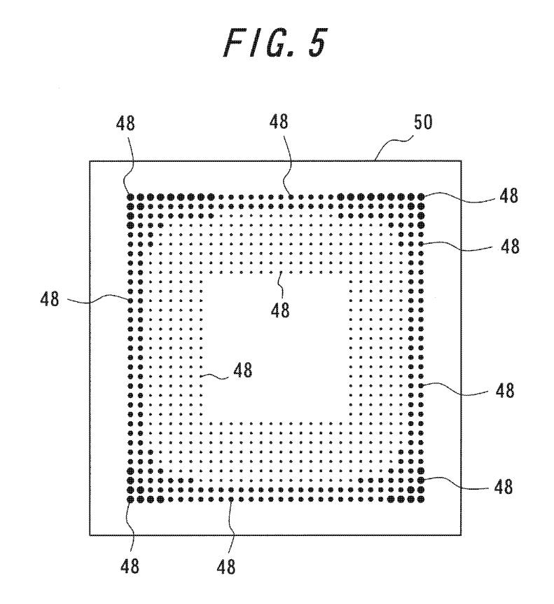

FIG. 1 is a view illustrating the configuration of the electric contact according to the invention. FIG. 2 includes a plan and a longitudinal sectional view of the electrical connector. FIG. 3 includes a partly enlarged plan view and a partly enlarged longitudinal sectional view of the electrical connector. FIGS. 4A to 4F are views for explaining the method for producing the electric contact according to the invention. FIG. 5 is a view for explaining the method for producing the electrical connector according to the invention.

The electrical connector of one embodiment of the invention comprises at least an elastomer, fine conductors and flexible printed circuit boards.

First, the configuration of the electric contact 20 will be explained with reference to FIG. 1. The electric contact 20 has a shape which extends in the form of a dome by plating in a hole 42 formed in a cover lay 46 located on a copper foil 40 and further plating higher than the cover lay 46 with a total of three times of plating. The extending electric contact is plated with gold over at least part adapted to contact a mating contact. The size of the electric contact 20 is in a relation in that its height is larger than the radius (one half of diameter) of the electric contact 20. The radius and the height may be suitably designed in consideration of space therearound and required height of the electric contact. Plating with copper is the most preferable for forming the electric contact.

The flexible printed circuit board 14 will be explained. The flexible printed circuit board 14 is provided with a plurality of electric contact elements 18 at locations corresponding to contacts of a mating connector. The electric contact elements 18 are each provided with an electric contact in the form of a hemisphere adapted to be optimized for the shape of the mating contact to facilitate the contact therebetween. The circuit board 14 is provided with a recess or through-hole (including through-groove) which is a relief for capacitors, IC chips, resistances and the like extending higher than the contacts of the mating connector and at a location within the center area corresponding to these members. The size of the recess or through-hole may be suitably designed so that the circuit board does not touch the capacitors, IC chips, resistances and the like extending higher than the contacts of the mating connector, and in consideration of the miniaturization of the connector, positional accuracy and the like.

The flexible printed circuit board 14 is formed with substantially U-shaped slits 22 about the electric contact elements 18, respectively. When the electric contact element 18 contacts a contact of the mating connector, the U-shaped slit 22 serves to cause sliding movement of the electric contact element 18 relative to the mating contact with the aid of the elasticity of the elastomer 16. The sliding movement of the electric contact element 18 is caused by the fact that by providing the U-shaped slit the electric contact element 18 is supported in a cantilevered manner so that upon contacting the mating contact, the electric contact element is deformed like a cantilever while contacting the mating contact, thereby causing sliding movement between the electric contact element 18 and the mating contact. The size of the U-shaped slits may be suitably designed in consideration of such a function, the miniaturization of the connector 10 and the like. As shown in FIG. 3, the electric contact 18 is connected to a through-hole 26 through a conductive portion 24, and the through-hole 26 is connected to a fine conductor 12. The size of the through-holes 26 may be suitably designed so as to be able to receive the fine conductors 12 and to be connected to the conductors by soldering or the like and in consideration of miniaturization of the connector 10 and strength of the fine conductors 12 and capability of connection.

The fine conductors 12 will then be explained. The fine conductor 12 is substantially cylindrical and of a two stepped shape having a thin diameter at both ends and a thick diameter at its center. The fine conductor 12 is made of a metal by cutting a rod of a metal superior in conductivity, for example, brass into a predetermined length and machining the both the end portions to a smaller diameter. Both the end portions are to be inserted in the through-holes 26 and therefore the diameter of both the end portions may be suitably designed so that both the end portions are received in the through-holes 26 and connected thereto by soldering. The center portion of the fine conductor 12 is to be embedded in the elastomer 16 and therefore the diameter of the center portion may be suitably designed in consideration of the miniaturization of the connector 10, narrowed pitches and conductivity. The lengths of the respective portions of the conductor may be suitably designed in consideration of the thicknesses of the flexible printed circuit boards 14 and the elastomer 16.

The elastomer 16 will then be explained. The elastomer 16 is formed with inserting holes 28 for inserting the fine conductors 12 thereinto, respectively. The diameter of the inserting holes 28 may be suitably designed so as to permit the fine conductors 12 to be inserted into the inserting holes 28 and in consideration of holding force for the fine conductors 12 and the like. The diameter of the inserting holes 28 is approximately 20 μm smaller than the diameter of the center portions of the conductors 12 in the illustrated embodiment. The elastomer 16 is preferably formed with a recess 32 at each of ends of the inserting holes 28 for preventing warp of the elastomer 16 caused by part of elastomer unexpectedly extending on a shoulder 30 of the fine conductor 12. The elastomer 16 is formed from silicon rubber or fluororubber.

Finally, the methods for producing the electric contact 20 and the electrical connector 10 will be explained with reference to FIGS. 4A to 4F and 5. First, the method for producing the electric contact 20 will be explained.

As a first step, as shown in FIG. 4A a cover lay 46 having a hole 42 of a diameter smaller than that of a copper foil 40 is fixed to the copper foil 40, and as shown in FIG. 4B the inside of the hole 42 of the cover lay 46 is plated so as to reach the upper surface of the cover lay to form a plate layer 44.

For the sake of clarity, the method is explained with respect to one electric contact 20 using a cover lay 46 having a single hole 42. However, in reality, a number of copper foils 40 are arranged on a board, and a cover lay 46 has a size sufficient to cover all the copper foils 40 on the board and is formed with a number of holes 42 which are the same number as that of the copper foils 40 and at locations corresponding to the copper foils 40. In this way, using one cover lay 46 a number of electric contacts 20 can be formed on the respective copper foils 40 on the board.

As a second step, as shown in FIG. 4C a dry film 50 having a hole 48 of a diameter smaller than that of the hole 42 of the cover lay 46 is installed on the cover lay 46, and as shown in FIG. 4D the inside of the hole 48 is plated so as to reach the upper surface of the dry film 50 to form a plate layer 44. As described above, in reality a dry film having a plurality of holes 48 is installed on the cover lay 46.

As a third step, as shown in FIG. 4E the dry film 50 is removed, and finally as shown in FIG. 4F the plate layer 44 is further plated to form a plate layer 44.

The method for producing the electrical connector will then be explained by referring to FIG. 5. The fine conductors 12 are embedded in the elastomer 16 as shown in FIGS. 2 and 3. The flexible printed circuit board 14 includes the pattern having the electric contact elements each provided with the electric contact adapted to contact a mating object. Such two circuit boards 14 are arranged on both sides of the elastomer 16 so that the through-holes 26 of the boards 14 coincide with the end portions of the fine conductors 12, respectively. The plurality of electric contacts produced as described above are arranged with predetermined pitches as shown in FIG. 2. With the arrangement as shown in FIG. 2, irregularities in adherence of plated metal may tend to occur depending upon positions of the electric contacts 20. In order to solve this problem, diameters of the holes 48 of the dry film 50 for plating are varied depending upon positions of the electric contacts 20. In the electrical connector 10 having the electric contacts 20 arranged with predetermined pitches in a substantially square area, diameters of holes 48 of the dry film 50 in the proximity of four corners of the square area are smaller than diameters of those in the proximity of four sides of the square area, and the diameters of those in the inner side of the area other than those in the proximities of the four corners and the four sides are larger than the diameters of those in the proximity of the four sides of the square area.

In the illustrated embodiment, the diameters of the holes 48 in the proximity of the four corners are 0.16 mm and the diameters in the proximity of the four sides are 0.18 mm, while the other diameters in the inner side are 0.2 mm. In this way, the electric contacts 20 become uniform in height. In FIG. 5, triple circles illustrate diameters of 0.16 mm, double circles 0.18 mm and single circles 0.2 mm.

Examples of applications of the inventions are electrical connectors fitted between circuit boards and electronic appliances, and are also electric contacts and methods for producing the contacts whose heights are as high as possible and uniform without increasing their radii.

While the invention has been particularly shown and described with reference to the preferred embodiments thereof, it will be understood by those skilled in the art that the foregoing and other changes in form and details can be made therein without departing from the spirit and scope of the invention.

What is claimed is:

1. A method for producing an electric contact extending from a copper foil, comprising steps of:
fixing a cover lay having a hole of a diameter smaller than that of said copper foil of a predetermined size to said copper foil, and plating said hole of the cover lay so as to reach the upper surface of the cover lay as a first step; installing a dry film having a hole of a diameter smaller than that of said hole of the cover lay onto said cover lay, and plating said hole of the dry film so as to reach the upper surface of the dry film as a second step; and after removal of said dry film, as a third step further plating the plate layers obtained in the first and second steps.

2. The method for producing an electric contact as set forth in claim 1, wherein the height of the produced electric contact is greater than the radius (one half of diameter) of the electric contact.

3. A method for producing an electrical connector including a plurality of said electric contacts arranged with predetermined pitches, wherein diameters of the holes of the dry film used in plating are changed depending upon positions of the electric contacts.

4. The method for producing an electrical connector as set forth in claim 3, wherein a plurality of said electric contacts are arranged with predetermined pitches in a substantially square area, and wherein diameters of said holes of the dry film in the proximity of four corners of the square area are smaller than diameters of those in the proximity of four sides of the square area, and diameters of those in the inner side of the area other than those in the proximities of the four corners and the four sides are larger than the diameters of those in the proximity of the four sides of the square area.
